(19) United States
(12) Patent Application Publication
(10) Pub. No.: US 2025/0022682 A1
(43) Pub. Date: Jan. 16, 2025

(54) PLASMA PROCESSING APPARATUS

(71) Applicant: Panasonic Intellectual Property Management Co., Ltd., Osaka (JP)

(72) Inventors: Shogo OKITA, HYOGO (JP); Takahiro MIYAI, OSAKA (JP); Yoshiyuki WADA, OSAKA (JP); Naoaki TAKEDA, OSAKA (JP); Toshiyuki TAKASAKI, OSAKA (JP); Hisao NAGAI, OSAKA (JP); Seiya NAGANO, OSAKA (JP)

(21) Appl. No.: 18/766,729

(22) Filed: Jul. 9, 2024

(30) Foreign Application Priority Data
Jul. 11, 2023 (JP) 2023-113881

(51) Int. Cl. H01J 37/32

(52) U.S. Cl. CPC H01J 37/3211; H01J 2237/334

(57) ABSTRACT

A plasma generation unit includes: a first coil that includes first conductors that are connected in parallel to each other; and a first distribution portion that distributes, to each of the first conductors, first high frequency power to be supplied to the first coil. The first distribution portion includes: a first input portion to which the first high frequency power is input; a first branch portion at which the first high frequency power input to the first input portion is divided and delivered into first branch lines; and second branch portions at each of which a corresponding one of the first branch lines branches out into second branch lines. Each of the second branch lines is connected to one of first application portions that are included in the first conductors. The first branch lines have a substantially equal length. The second branch lines have a substantially equal length.

### CROSS REFERENCE TO RELATED APPLICATION

The present application is based on and claims priority under 35 U.S.C. § 119 with respect to the Japanese Patent Application No. 2023-113881 filed on Jul. 11, 2023, of which entire content is incorporated herein by reference into the present application.

### TECHNICAL FIELD

The present disclosure relates to a plasma processing apparatus.

### BACKGROUND

Conventionally, a plasma processing apparatus that processes a workpiece by using a plasma is known as disclosed in, for example, Patent Literature 1 (JP2012-74464A). Patent Literature 1 discloses a plasma processing apparatus that includes a chamber, a dielectric window, and an inner coil, an intermediate coil, and an outer coil that are provided above the dielectric window, and is configured to generate a plasma in the chamber by applying high frequency power to the coils.

However, as shown in FIG. 2 of Patent Literature 1, in the plasma processing apparatus disclosed in Patent Literature 1, coil segments that correspond to the coils have lengths that are significantly different from each other, and it is therefore assumed that the in-plane uniformity of plasma (or in other words, uniformity within the horizontal plane in the plasma density distribution in the chamber) is not so high. It is desirable that the in-plane uniformity of plasma is as high as possible in order to uniformly process the entire workpiece such as a wafer. Under the circumstances described above, it is an object of the present disclosure to enhance the in-plane uniformity of plasma.

### SUMMARY

An aspect of the present disclosure relates to a plasma processing apparatus. The plasma processing apparatus includes: a chamber that has an opening; a stage that is provided in the chamber and on which a workpiece is to be placed; a dielectric member that closes the opening; and a plasma generation unit that is provided on a side opposite to the chamber across the dielectric member, and generates a plasma in the chamber. The plasma generation unit includes: a first coil that includes a plurality of first conductors that are connected in parallel to each other; and a first distribution portion that distributes, to each of the first conductors, first high frequency power to be supplied to the first coil. The first distribution portion includes: a first input portion to which the first high frequency power is input; a first branch portion at which the first high frequency power input to the first input portion is divided and delivered into a plurality of first branch lines; and a plurality of second branch portions at each of which a corresponding one of the first branch lines branches out into a plurality of second branch lines. Each of the second branch lines is connected to one of first application portions that are included in the first conductors. The first branch lines have a substantially equal length. The second branch lines have a substantially equal length.

According to the present disclosure, it is possible to enhance the in-plane uniformity of plasma.

### BRIEF DESCRIPTION OF THE DRAWINGS

FIG. 1 is a cross-sectional view schematically showing an example of a plasma processing apparatus according to the present disclosure.

FIG. 2 is a plan view schematically showing a plasma generation unit, with structural elements that constitute first and second distribution portions being hatched with dots.

FIG. 3 is a plan view schematically showing a first coil and a second coil.

FIG. 4 shows a simulation result showing a radical density distribution of the plasma processing apparatus according to the present disclosure.

### DETAILED DESCRIPTION

A plasma processing apparatus according to an embodiment of the present disclosure will be described below by way of an example. However, the present disclosure is not limited to the example given below. In the following description, specific numerical values and materials may be shown as examples. However, other numerical values and materials may also be used as long as the advantageous effects of the present disclosure can be obtained.

The plasma processing apparatus according to the present disclosure is an apparatus for plasma processing a workpiece. The plasma processing apparatus may be, for example, a plasma etching apparatus, a plasma dicer, a plasma ashing apparatus, or a plasma CVD apparatus. The plasma processing apparatus includes a chamber, a stage, a dielectric member, and a plasma generation unit.

The chamber has an opening. The chamber may have a hollow cylindrical shape. The chamber may have the opening on top. The opening may be open in the upward direction. The chamber may be electrically grounded.

The stage is provided in the chamber, and a workpiece is placed on the stage. The stage may have a horizontal placement surface on which a workpiece is placed. The stage may have a flow path through which a cooling medium for cooling the workpiece during plasma processing. The stage may have an electrostatic adsorption mechanism for adsorbing the workpiece. The stage may include a bottom electrode to which high frequency power is applied. The workpiece may be, for example, a semiconductor substrate to be singulated into individual chips through plasma etching. The semiconductor substrate includes a plurality of element regions and a dividing region that defines the element regions. The element regions each include, for example, a semiconductor layer and a wiring layer. By etching the dividing region, element chips, each including a semiconductor layer and a wiring layer, can be obtained. The workpiece may be placed on the stage while being supported by a carrier. The carrier may be, for example, a resin sheet whose outer periphery portion is held by a frame.

The dielectric member closes the opening of the chamber. The dielectric member may have a plate shape that includes a horizontally extending region. The dielectric member may be made of a ceramic such as, for example, quartz, alumina, or aluminum nitride. The dielectric member may be made mainly of quartz.

The plasma generation unit is provided on a side opposite to the chamber across the dielectric member, and generates a plasma in the chamber. The plasma generation unit may be provided on the dielectric member.

The plasma generation unit includes a first coil and a first distribution portion. The first coil includes a plurality of (for example, four) first conductors that are connected in parallel to each other. The plurality of first conductors may have a substantially equal length. The first distribution portion distributes, to each of the first conductors, first high frequency power to be supplied to the first coil. The first distribution portion may be made of a conductor.

The first distribution portion includes a first input portion, a first branch portion, and a second branch portion. The first high frequency power is input to the first input portion. At the first branch portion, the first high frequency power input to the first input portion is divided and delivered into a plurality of (for example, two) first branch lines. Each of the first branch lines branches out into a plurality of (for example, two) second branch lines at the second branch portion.

Each of the second branch lines is connected to one of first application portions that are included in the first conductors. Each of the first conductors may further include a first ground portion that is electrically connected to the chamber. One second branch line may be connected to one first conductor. In other words, the plurality of second branch lines and the plurality of first conductors may be in one-to-one correspondence with each other.

With the configuration described above, the first high frequency power input to the first input portion is divided and delivered into a plurality of first branch lines, then further divided and delivered into a plurality of second branch lines, and flows into the plurality of first conductors included in the first coil. As a result, a high-frequency magnetic field is generated from the first coil, and the high-frequency magnetic field acts on a raw material gas introduced into the chamber to generate a plasma.

Here, in the plasma processing apparatus according to the present disclosure, the first branch lines have a substantially equal length, and the second branch lines have a substantially equal length. That is, the length of an electric current path of the first distribution portion that extends to each of the first conductors (or in other words, the length of an electric current path that extends from the first input portion to the first application portion of each of the first conductors via the first branch line and the second branch line) is substantially equal. Accordingly, high frequency currents that flow through the plurality of first conductors are equal to each other, and thus the in-plane uniformity of the plasma generated by the first coil is enhanced.

In the specification of the present application, the expression “a member A and a member B have a substantially equal length” means that, when the length of one of the member A and the member B is set to 100 (reference value), the length of the other member is 95 or more and 105 or less. Also, the term “the length of a member” refers to a dimension of the member that extends along the shape of the member.

Each of the plurality of first conductors may have a spiral shape that extends from the first application portion that is provided at a center side of the dielectric member to the first ground portion that is provided at an outer periphery side of the dielectric member, and may be placed in a rotationally symmetric manner about the center of the dielectric member. The first input portion may be provided at the outer periphery side of the dielectric member relative to the first branch portion. The first branch portion may be provided at the center side of the dielectric member relative to the second branch portions. With the arrangement of the constituent elements described above, an electric current generated by the first high frequency power input to the first input portion flows toward the first branch portion, or in other words, toward the center side of the dielectric member, and then flows toward the second branch portions via the first branch lines, or in other words, toward the outer periphery side of the dielectric member and then into the first conductors of the first coil via the second branch lines. In each of the first conductors of the first coil, the electric current flows from the first application portion toward the first ground portion, or in other words, from the center side of the dielectric member to the outer periphery side of the dielectric member. The first branch lines and the second branch lines are provided at the center side of the dielectric member relative to the first conductors, and it is thereby possible to suppress a situation in which magnetic fields generated by electric currents that flow through the first branch lines and the second branch lines interfere with the first conductors.

The first branch portion may be provided at the outer periphery side of the dielectric member relative to the center of the dielectric member. The first branch portion is provided at a position closest to the center of the dielectric member among the constituent elements of the first distribution portion. By providing the first branch portion at the outer periphery side of the dielectric member relative to the center of the dielectric member, it is possible to ensure a space around the center of the dielectric member. The space can be effectively used to, for example, place a measurement apparatus for measuring the state of the workpiece during plasma processing (for example, a laser interferometer for measuring film thickness or an infrared sensor for measuring substrate temperature).

The plasma generation unit may further include: a second coil that is provided at a center side of the dielectric member relative to the first application portions of the first coil, and includes a plurality of (for example, two) second conductors that are connected in parallel to each other; and a second distribution portion that distributes, to each of the second conductors, second high frequency power to be supplied to the second coil. The second distribution portion may include: a second input portion to which the second high frequency power is input; and a third branch portion at which the second high frequency power input to the second input portion is divided and delivered into a plurality of (for example, two) third branch lines. Each of the third branch lines may be connected to one of second application portions that are included in the second conductors. The third branch lines may have a substantially equal length. With this configuration, the second coil is provided at the center side of the dielectric member relative to the first coil. In this context, the first coil may also be referred to as “outer coil”, and the second coil may also be referred to as “inner coil”. An electric current generated by the second high frequency power supplied to the second coil flows into the plurality of third branch lines via the second input portion, and then flows into the plurality of second conductors via the second application portions. As a result, a high-frequency magnetic field is generated from the second coil, and the high-frequency magnetic field acts on a raw material gas introduced into the chamber to generate a plasma. Also, the third branch lines have a substantially equal length, and thus electric current paths of the second distribution portion that extend to the second conductors have a substantially equal length. Accordingly, high frequency currents that flow through the plurality of second conductors are equal to each other, and thus the in-plane uniformity of the plasma generated by the second coil is enhanced.

The third branch portion may be provided at an outer periphery side of the dielectric member relative to the center of the dielectric member. By providing the third branch portion at the outer periphery side of the dielectric member relative to the center of the dielectric member, it is possible to ensure a space around the center of the dielectric member. The space can be effectively used to, for example, place a measurement apparatus for measuring the state of the workpiece during plasma processing (for example, a laser interferometer for measuring film thickness or an infrared sensor for measuring substrate temperature).

The third branch portion may be provided at the center side of the dielectric member relative to the first application portions of the first coil. With this configuration, the third branch lines that are connected to the third branch portion are provided at the center side of the dielectric member relative to the first application portions that are provided at positions closest to the center of the dielectric member among the constituent elements of the first coil. Accordingly, it is possible to suppress a situation in which magnetic fields generated by high frequency currents that flow through the third branch lines interfere with the first coil.

The distance between the third branch portion and the dielectric member may be smaller than the distance between the first branch portion and the dielectric member. It is often the case that high frequency power larger than that introduced into the third branch lines of the second coil (inner coil) is introduced into the first branch lines and the second branch lines of the first coil (outer coil). In other words, it is often the case that the first high frequency power is larger than the second high frequency power. In contrast, with the configuration described above, the first branch lines and the second branch lines are spaced apart from the dielectric member, or in other words, from the chamber, than the third branch lines are. That is, by providing the first branch lines and the second branch lines (or the first distribution portion), into which relatively large high frequency power is introduced, at positions spaced apart from the chamber, it is possible to suppress a situation in which a magnetic field generated by high frequency current that flows through the first distribution portion affects the plasma generated in the chamber.

The plasma generation unit may include: a first application line that connects the first input portion and the first branch portion; and a second application line that connects the second input portion and the third branch portion. The first application line and the second application line may be provided such that the first application line and the second application line do not overlap each other when viewed in a plan view. With this configuration, the first application line through which an electric current generated by the first high frequency power flows and the second application line through which an electric current generated by the second high frequency power flows are provided such that they do not overlap each other when viewed in a plan view, and it is therefore possible to suppress magnetic field interference between the first and second application lines. The first application line and the second application line may be displaced from each other by an angle of, for example, 30° or more and 180° or less when viewed in a plan view.

As described above, according to the present disclosure, by configuring the first branch lines to have the same length and the second branch lines to have the same length, it is possible to enhance the in-plane uniformity of plasma. Furthermore, according to the present disclosure, by configuring the third branch lines to have the same length, it is possible to further enhance the in-plane uniformity of plasma.

Hereinafter, an example of a plasma processing apparatus according to the present disclosure will be described specifically with reference to the drawings. The structural elements described above can be used as structural elements of the plasma processing apparatus described below as an example. The structural elements of the plasma processing apparatus described below as an example can be changed based on the description given above. Also, features that will be described below may be applied to the embodiment described above. Among the structural elements of the plasma processing apparatus described below as an example, those that are not essential to the plasma processing apparatus of the present disclosure may be omitted. The diagrams shown below are schematic representations, and thus are not necessarily true to the actual shape and the actual number of members.

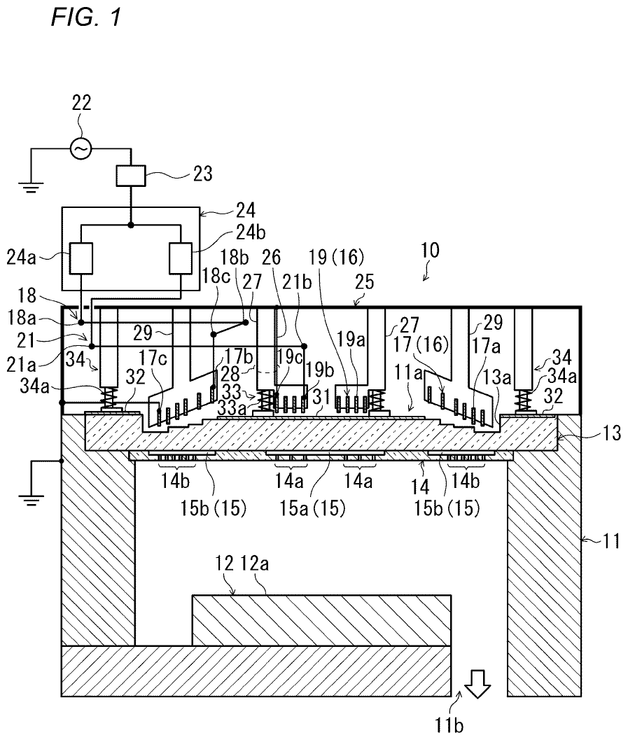

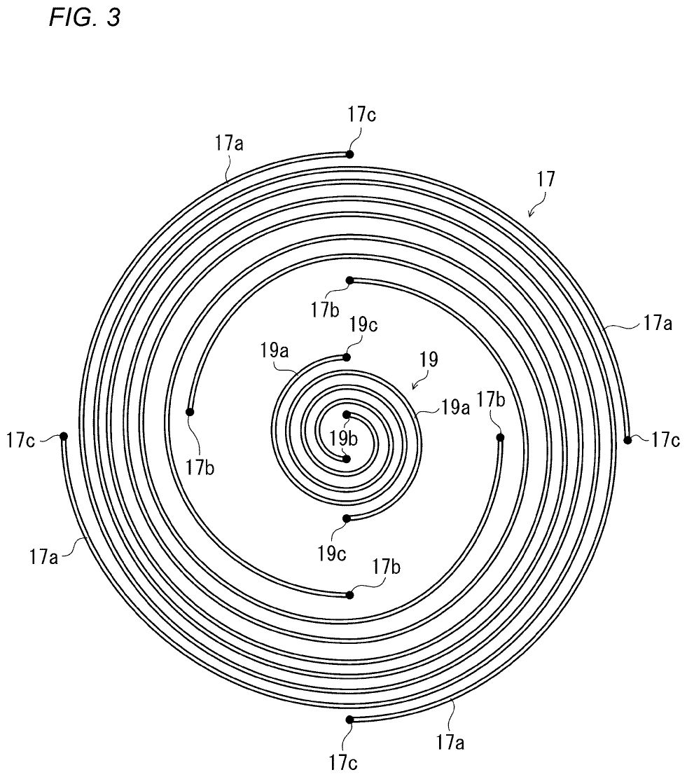

A plasma processing apparatus 10 according to the present embodiment is an apparatus for plasma processing a workpiece (for example, a semiconductor substrate). The plasma processing apparatus 10 according to the present embodiment is a plasma dicer, but is not limited thereto. As shown in FIGS. 1 to 3, the plasma processing apparatus 10 includes a chamber 11, a stage 12, a dielectric member 13, a cover 14, a gas introducing path 15, a plasma generation unit 16, a metal cover 25, a first pillar 27, a second pillar 29, a first heater 31, a second heater 32, a first pressing portion 33, a second pressing portion 34, a high frequency power supply 22, a matching device 23, and a distribution device 24.

The chamber 11 has an opening 11a on top. The chamber 11 has a hollow cylindrical shape, but the shape of the chamber 11 is not limited thereto. The opening 11a is open in the upward direction. The chamber 11 has a gas discharge port 11b that is provided on the outer periphery side relative to the stage 12 so as to discharge a raw material gas used in plasma processing. A gas discharge apparatus (not shown) is connected to the gas discharge port 11b. The chamber 11 is made of a conductive member (for example, a metal). The chamber 11 is grounded.

The stage 12 is provided in the chamber 11, and a workpiece is placed on the stage. The stage 12 has a horizontal placement surface 12a on which the workpiece is placed. The stage 12 includes a flow path (not shown) through which a cooling medium for cooling the workpiece flows during plasma processing. The stage 12 includes an electrostatic adsorption mechanism (not shown) for adsorbing the workpiece. The stage 12 includes a bottom electrode (not shown) to which high frequency power is applied.

The dielectric member 13 closes the opening 11a of the chamber 11. The dielectric member 13 has a plate shape that includes a horizontally extending region. The dielectric member 13 is made of quartz, but the material of the dielectric member is not limited thereto.

The cover 14 is placed in the chamber 11 to cover the dielectric member 13. The cover 14 covers an underside of the dielectric member 13. The cover 14 includes a plurality of first gas holes 14a that are formed at positions that overlap a central region of the dielectric member 13 and a plurality of second gas holes 14b that are formed at positions that overlap a peripheral region of the dielectric member 13. The first gas holes 14a and the second gas holes 14b extend through the cover 14 in the thickness direction of the cover 14 (the up down direction in FIG. 1). The first gas holes 14a and the second gas holes 14b are in communication with a space of the chamber 11 in which the stage 12 is provided. The plurality of first gas holes 14a are spaced in the radial direction and the circumferential direction. The plurality of second gas holes 14b are spaced in the radial direction and the circumferential direction. The cover 14 is made of aluminum nitride, but the material of the cover 14 is not limited thereto.

The gas introducing path 15 is formed between the dielectric member 13 and the cover 14, and a raw material gas is introduced into the gas introducing path 15. The gas introducing path 15 includes a first gas introducing path 15a that is in communication with the first gas holes 14a and a second gas introducing path 15b that is in communication with the second gas holes 14b. Each of the first gas introducing path 15a and the second gas introducing path 15b is constituted by a groove formed in the cover 14. The first gas introducing path 15a and the second gas introducing path 15b are separated from each other. The first gas introducing path 15a and the second gas introducing path 15b are in communication with the outside of the chamber 11. A gas source (not shown) is connected to each of the first gas introducing path 15a and the second gas introducing path 15b.

The plasma generation unit 16 is provided on a side (on the upper side in FIG. 1) opposite to the chamber 11 across the dielectric member 13, and generates a plasma in the chamber 11. The plasma generation unit 16 includes a first coil 17, a first distribution portion 18, a second coil 19, and a second distribution portion 21.

The first coil 17 includes a plurality of (in this example, four) first conductors 17a that are connected in parallel to each other. The plurality of first conductors 17a have a substantially equal length. Each of the first conductors 17a has a spiral shape that extends from a first application portion 17b that is provided at a center side of the dielectric member 13 to a first ground portion 17c that is provided at an outer periphery side of the dielectric member 13. The first ground portion 17c may be connected to the metal cover 25.

The first coil 17 is provided on the peripheral region of the dielectric member 13. In the first coil 17, the four first conductors 17a are displaced at an angle of 90° to each other in the circumferential direction. In other words, the four first conductors 17a are placed in a rotationally symmetric manner to each other about the center of the dielectric member 13. With this configuration, variation in plasma density in the circumferential direction can be reduced.

The first distribution portion 18 distributes, to each of the first conductors 17a, first high frequency power to be supplied to the first coil 17 (a portion of high frequency power output from the high frequency power supply 22). The first distribution portion 18 is made of a conductor.

The first distribution portion 18 includes a first input portion 18a, a first branch portion 18b, and second branch portions 18c. The first high frequency power is input to the first input portion 18a. The first branch portion 18b is connected to the first input portion 18a via a first application line 18d. At the first branch portion 18b, the first high frequency power input to the first input portion 18a is divided and delivered into a plurality of (in this example, two) first branch lines 18e. Each of the first branch lines 18e branches out into a plurality of (in this example, two) second branch lines 18f at the second branch portion 18c. The second branch lines 18f are connected to the first application portions 17b of the first conductors 17a.

The first input portion 18a is provided at the outer periphery side of the dielectric member 13 relative to the first branch portion 18b. The first branch portion 18b is provided at the center side of the dielectric member 13 relative to the second branch portions 18c. The first branch portion 18b is provided at the outer periphery side of the dielectric member 13 relative to the center of the dielectric member 13.

The first branch lines 18e have a substantially equal length. The second branch lines 18f have a substantially equal length. Accordingly, electric current paths of the first distribution portion 18 that extend to the first conductors 17a have a substantially equal length, and thus the in-plane uniformity of the plasma generated by the first coil 17 is enhanced.

The second coil 19 is provided at the center side of the dielectric member 13 relative to the first application portions 17b of the first coil 17. The second coil 19 includes a plurality of (in this example, two) second conductors 19a that are connected in parallel to each other. The plurality of second conductors 19a have a substantially equal length. Each of the second conductors 19a has a spiral shape that extends from a second application portion 19b that is provided at the center side of the dielectric member 13 to a second ground portion 19c that is provided at the outer periphery side of the dielectric member 13. The second ground portion 19c may be electrically connected to the metal cover 25.

The second coil 19 is provided on the central region of the dielectric member 13. In the second coil 19, the two second conductors 19a are displaced at an angle of 180° to each other in the circumferential direction. In other words, the two second conductors 19a are placed in a rotationally symmetric manner to each other about the center of the dielectric member 13. With this configuration, variation in plasma density in the circumferential direction can be reduced.

The second distribution portion 21 distributes, to each of the second conductors 19a, second high frequency power to be supplied to the second coil 19 (a portion of the high frequency power output from the high frequency power supply 22). The second distribution portion 21 is made of a conductor.

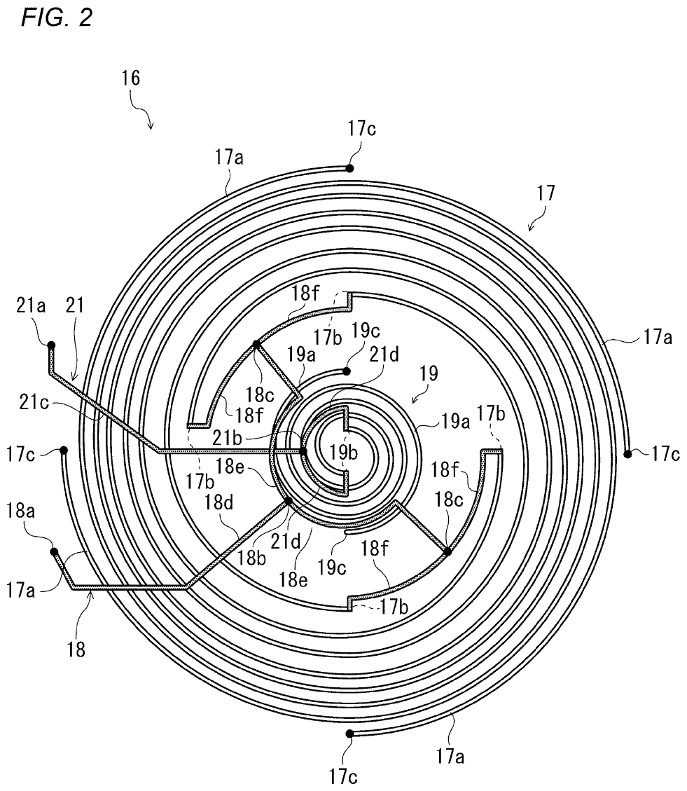

The second distribution portion 21 includes a second input portion 21a and a third branch portion 21b. The second high frequency power is input to the second input portion 21a. The third branch portion 21b is connected to the second input portion 21a via a second application line 21c. At the third branch portion 21b, the second high frequency power input to the second input portion 21a is divided and delivered into a plurality of (in this example, two) third branch lines 21d. Each of the third branch lines 21d is connected to one of the second application portions 19b of the second conductors 19a. The second application line 21c is provided so as not to overlap the first application line 18d when viewed in a plan view (FIG. 2).

The third branch portion 21b is provided at the outer periphery side of the dielectric member 13 relative to the center of the dielectric member 13. The third branch portion 21b is provided at the center side of the dielectric member 13 relative to the first application portions 17b of the first coil 17. The distance between the third branch portion 21b and the dielectric member 13 (the distance extending in the up down direction) is smaller than the distance between the first branch portion 18b and the dielectric member 13 (the distance extending in the up down direction) (FIG. 1).

The third branch lines 21d have a substantially equal length. Accordingly, electric current paths of the second distribution portion 21 that extend to the second conductors 19a have a substantially equal length, and thus the in-plane uniformity of the plasma generated by the second coil 19 is enhanced.

The metal cover 25 covers the first coil 17 and the second coil 19. The metal cover 25 is provided on the upper side of the chamber 11, and electrically connected to the chamber 11. The metal cover 25 has a cylindrical shape with its upper end being closed, but the shape of the metal cover 25 is not limited thereto. The metal cover 25 may be made of, for example, aluminum.

The first pillar 27 is provided on the upper side of the central region of the dielectric member 13. The first pillar 27 may be made of an insulator. The first pillar 27 is supported by the metal cover 25. The first pillar 27 supports the second coil 19. The first pillar 27 supports a conductive member 26 that is connected to the second ground portion 19c of the second coil 19 via a fixing member 28. The conductive member 26 is electrically connected to the metal cover 25 above the second coil 19. The conductive member 26 does not extend above the first coil 17.

The second pillar 29 is provided on the upper side of the peripheral region of the dielectric member 13. The second pillar 29 is made of an insulator. The second pillar 29 is supported by the metal cover 25. The second pillar 29 supports the first coil 17.

The first heater 31 and the second heater 32 are provided on an upper surface of the dielectric member 13, and heat the dielectric member 13 during plasma processing. The first heater 31 is provided in a region closer to the center of the dielectric member 13 relative to the second heater 32.

The first pressing portion 33 and the second pressing portion 34 respectively press the first heater 31 and the second heater 32 against the dielectric member 13. The first pressing portion 33 is provided between the first pillar 27 and the first heater 31. The first pressing portion 33 includes a first spring 33a for pressing the first heater 31 against the dielectric member 13. The second pressing portion 34 is provided between the metal cover 25 and the second heater 32. The second pressing portion 34 includes a second spring 34a for pressing the second heater 32 against the dielectric member 13.

The high frequency power supply 22 supplies high frequency power (for example, 3 to 30 MHz AC power) to the plasma generation unit 16. The high frequency power supply 22 is connected to the first input portion 18a of the first distribution portion 18 and the second input portion 21a of the second distribution portion 21 via the matching device 23 and the distribution device 24.

The matching device 23 is connected to the high frequency power supply 22. The matching device 23 is configured to match an impedance (input impedance) of the high frequency power supply 22 to a post-stage impedance (load impedance) of the matching device 23.

The distribution device 24 is connected between the matching device 23 and the plasma generation unit 16. The distribution device 24 includes: a first distribution circuit 24a that distributes a portion of high frequency power (first high frequency power) output from the high frequency power supply 22 to the first coil 17; and a second distribution circuit 24b that distributes a portion of the high frequency power (second high frequency power) to the second coil 19. The first distribution circuit 24a and the second distribution circuit 24b are connected in parallel to each other.

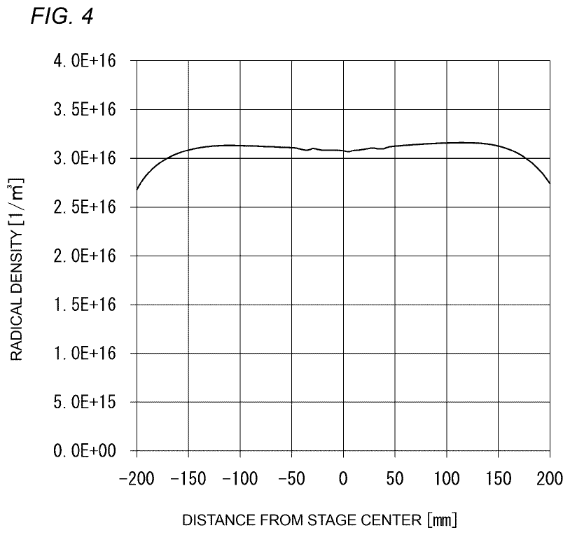

A simulation was performed to obtain a plasma distribution of the plasma processing apparatus 10 according to the present embodiment. The plasma generation unit 16 used in the simulation had the following structure: the first coil 17 had an inner diameter of about 220 mm and an outer diameter of about 390 mm; and the second coil 19 had an inner diameter of about 80 mm and an outer diameter of about 140 mm. Also, the plasma generation condition used in the simulation was as follows: the high frequency power and the frequency applied to the first coil 17 were set to 5000 W and 13.56 MHz, respectively; the high frequency power and the frequency applied to the second coil 19 were set to 700 W and 13.56 MHz, respectively; and an argon gas was used as the raw material gas. FIG. 4 shows a graph showing a radical density distribution obtained at a position 5 mm above the stage 12, with the horizontal axis indicating the distance from the center of the stage 12, and the vertical axis indicating radical density at each position. The average value of the radical density and the in-plane uniformity were calculated based on the graph, and found to be 3.12×1016 [1/m3] and 1.5 [%], respectively, from which it can be seen that a favorable high-density distribution was obtained.

### ADDITIONAL STATEMENT

Based on the description of the embodiment given above, the following techniques are disclosed.

### Technique 1

A plasma processing apparatus including:
a chamber that has an opening;
a stage that is provided in the chamber and on which a workpiece is to be placed;
a dielectric member that closes the opening; and
a plasma generation unit that is provided on a side opposite to the chamber across the dielectric member, and generates a plasma in the chamber,
wherein the plasma generation unit includes:
a first coil that includes a plurality of first conductors that are connected in parallel to each other; and
a first distribution portion that distributes, to each of the first conductors, first high frequency power to be supplied to the first coil,
the first distribution portion includes:
a first input portion to which the first high frequency power is input;
a first branch portion at which the first high frequency power input to the first input portion is divided and delivered into a plurality of first branch lines; and
a plurality of second branch portions at each of which a corresponding one of the first branch lines branches out into a plurality of second branch lines,
each of the second branch lines is connected to one of first application portions that are included in the first conductors,
the first branch lines have a substantially equal length, and
the second branch lines have a substantially equal length.

### Technique 2

The plasma processing apparatus in accordance with technique 1,
wherein each of the plurality of first conductors has a spiral shape that extends from the first application portion that is provided at a center side of the dielectric member to a first ground portion that is provided at an outer periphery side of the dielectric member, and is placed in a rotationally symmetric manner about the center of the dielectric member,
the first input portion is provided at the outer periphery side of the dielectric member relative to the first branch portion, and
the first branch portion is provided at the center side of the dielectric member relative to the second branch portions.

### Technique 3

The plasma processing apparatus in accordance with technique 2,
wherein the first branch portion is provided at the outer periphery side of the dielectric member relative to the center of the dielectric member.

### Technique 4

The plasma processing apparatus in accordance with any one of techniques 1 to 3,
wherein the plasma generation unit further includes:
a second coil that is provided at a center side of the dielectric member relative to the first application portions of the first coil, and includes a plurality of second conductors that are connected in parallel to each other; and
a second distribution portion that distributes, to each of the second conductors, second high frequency power to be supplied to the second coil,
the second distribution portion includes:
a second input portion to which the second high frequency power is input; and
a third branch portion at which the second high frequency power input to the second input portion is divided and delivered into a plurality of third branch lines,
each of the third branch lines is connected to one of second application portions that are included in the second conductors, and
the third branch lines have a substantially equal length.

### Technique 5

The plasma processing apparatus in accordance with technique 4,
wherein the third branch portion is provided at an outer periphery side of the dielectric member relative to the center of the dielectric member.

### Technique 6

The plasma processing apparatus in accordance with technique 5,
wherein the third branch portion is provided at the center side of the dielectric member relative to the first application portions of the first coil.

### Technique 7

The plasma processing apparatus in accordance with any one of techniques 4 to 6,
wherein a distance between the third branch portion and the dielectric member is smaller than a distance between the first branch portion and the dielectric member.

### Technique 8

The plasma processing apparatus in accordance with any one of techniques 4 to 7,
wherein the plasma generation unit includes:
a first application line that connects the first input portion and the first branch portion; and
a second application line that connects the second input portion and the third branch portion, and
the first application line and the second application line are provided such that the first application line and the second application line do not overlap each other when viewed in a plan view.

The present disclosure is applicable to a plasma processing apparatus.

### REFERENCE NUMERALS

10: plasma processing apparatus
11: chamber
11a: opening
11b: gas discharge port
12: stage
12a: placement surface
13: dielectric member
14: cover
14a: first gas hole
14b: second gas hole
15: gas introducing path
15a: first gas introducing path
15b: second gas introducing path
16: plasma generation unit
17: first coil
17a: first conductor
17b: first application portion
17c: first ground portion
18: first distribution portion
18a: first input portion
18b: first branch portion
18c: second branch portion
18d: first application line
18e: first branch line
18f: second branch line
19: second coil
19a: second conductor
19b: second application portion
19c: second ground portion
21: second distribution portion
21a: second input portion
21b: third branch portion
21c: second application line
21d: third branch line
22: high frequency power supply
23: matching device
24: distribution device
24a: first distribution circuit
24b: second distribution circuit
25: metal cover
26: conductive member
27: first pillar
28: fixing member
29: second pillar
31: first heater
32: second heater
33: first pressing portion
33a: first spring
34: second pressing portion
34a: second spring

What is claimed is:

1. A plasma processing apparatus comprising:
a chamber that has an opening;
a stage that is provided in the chamber and on which a workpiece is to be placed;
a dielectric member that closes the opening; and
a plasma generation unit that is provided on a side opposite to the chamber across the dielectric member, and generates a plasma in the chamber,
wherein the plasma generation unit includes:
a first coil that includes a plurality of first conductors that are connected in parallel to each other; and
a first distribution portion that distributes, to each of the first conductors, first high frequency power to be supplied to the first coil,
the first distribution portion includes:
a first input portion to which the first high frequency power is input;
a first branch portion at which the first high frequency power input to the first input portion is divided and delivered into a plurality of first branch lines; and
a plurality of second branch portions at each of which a corresponding one of the first branch lines branches out into a plurality of second branch lines,
each of the second branch lines is connected to one of first application portions that are included in the first conductors,
the first branch lines have a substantially equal length, and
the second branch lines have a substantially equal length.

2. The plasma processing apparatus in accordance with claim 1,
wherein each of the plurality of first conductors has a spiral shape that extends from the first application portion that is provided at a center side of the dielectric member to a first ground portion that is provided at an outer periphery side of the dielectric member, and is placed in a rotationally symmetric manner about the center of the dielectric member,
the first input portion is provided at the outer periphery side of the dielectric member relative to the first branch portion, and
the first branch portion is provided at the center side of the dielectric member relative to the second branch portions.

3. The plasma processing apparatus in accordance with claim 2,
wherein the first branch portion is provided at the outer periphery side of the dielectric member relative to the center of the dielectric member.

4. The plasma processing apparatus in accordance with claim 1,
wherein the plasma generation unit further includes:
a second coil that is provided at a center side of the dielectric member relative to the first application portions of the first coil, and includes a plurality of second conductors that are connected in parallel to each other; and
a second distribution portion that distributes, to each of the second conductors, second high frequency power to be supplied to the second coil,
the second distribution portion includes:
a second input portion to which the second high frequency power is input; and
a third branch portion at which the second high frequency power input to the second input portion is divided and delivered into a plurality of third branch lines,
each of the third branch lines is connected to one of second application portions that are included in the second conductors, and
the third branch lines have a substantially equal length.

5. The plasma processing apparatus in accordance with claim 4,
wherein the third branch portion is provided at an outer periphery side of the dielectric member relative to the center of the dielectric member.

6. The plasma processing apparatus in accordance with claim 5,
wherein the third branch portion is provided at the center side of the dielectric member relative to the first application portions of the first coil.

7. The plasma processing apparatus in accordance with claim 4,
wherein a distance between the third branch portion and the dielectric member is smaller than a distance between the first branch portion and the dielectric member.

8. The plasma processing apparatus in accordance with claim 4,
wherein the plasma generation unit includes:
a first application line that connects the first input portion and the first branch portion; and
a second application line that connects the second input portion and the third branch portion, and
the first application line and the second application line are provided such that the first application line and the second application line do not overlap each other when viewed in a plan view.
